(19) United States
(12) Patent Application Publication
(10) Pub. No.: US 2026/0182452 A1
(43) Pub. Date: Jun. 25, 2026

(54) PRINTED CIRCUIT BOARD AND METHOD FOR MANUFACTURING SAME, AND SEMICONDUCTOR DEVICE

(71) Applicant: Resonac Corporation, Minato-ku, Tokyo (JP)

(72) Inventors: Kazue HIRANO, Minato-ku, Tokyo (JP); Masaya TOBA, Minato-ku, Tokyo (JP)

(21) Appl. No.: 18/854,547

(22) PCT Filed: Apr. 8, 2022
(86) PCT No.: PCT/JP2022/017402

§ 371 Date: Oct. 7, 2024

(51) Int. Cl. H10W 90/00

(52) U.S. Cl. CPC H10W 90/00; H10W 90/724; H10W 90/734; H10W 90/754

(57) ABSTRACT

A printed circuit board including a wiring portion including a wiring layer, and an electrode pad provided on the wiring portion and connected to the wiring layer. A connection surface that is a surface of the electrode pad on a side opposite to the wiring portion has an arithmetic mean roughness Ra of 0.5 μm or more and 2.0 μm or less. The printed circuit board may further include a surface insulating resin layer provided on the surface of the wiring portion on the electrode pad side and having an opening configured to expose the electrode pad.

### TECHNICAL FIELD

The present disclosure relates to a printed circuit board, a connection method thereof, and a semiconductor device.

### BACKGROUND ART

In a printed circuit board having a wiring layer and an insulating layer, cracks may occur at an interface between the wiring layer and the insulating layer due to thermal stress associated with mounting of a semiconductor chip or the like (for example, Patent Literature 1).

### CITATION LIST

### Patent Literature

Patent Literature 1: Japanese Unexamined Patent Publication No. 2017-157666

### SUMMARY OF INVENTION

### Technical Problem

An aspect of the present disclosure relates to a printed circuit board including an electrode pad exposed in an opening of an insulating resin layer, and suppressing occurrence of a defect in the insulating resin layer due to a temperature change.

### Solution to Problem

An aspect of the present disclosure relates to a printed circuit board comprising a wiring portion including a wiring layer, and an electrode pad provided on the wiring portion and connected to the wiring layer. A connection surface that is a surface of the electrode pad on a side opposite to the wiring portion has an arithmetic mean roughness Ra of 0.5 μm or more and 2.0 μm or less.

Another aspect of the present disclosure relates to a semiconductor device including the printed circuit board and a semiconductor chip mounted on the printed circuit board.

Still another aspect of the present disclosure relates to a method for manufacturing a printed circuit board, the method including: preparing a wiring structure comprising a wiring portion comprising a wiring layer and an electrode pad provided on the wiring portion; and processing a connection surface that is a surface of the electrode pad on a side opposite to the wiring portion so that the connection surface has a surface having an arithmetic mean roughness Ra of 0.5 μm or more and 2.0 μm or less.

### Advantageous Effects of Invention

With regard to a printed circuit board having an electrode pad exposed in an opening of an insulating resin layer, the occurrence of defects in the insulating resin layer due to temperature change can be suppressed. Therefore, even in a case where the semiconductor device has fine wiring, high insulation reliability can be easily maintained.

### BRIEF DESCRIPTION OF DRAWINGS

FIG. 1 is a process diagram illustrating an example of a method for manufacturing a printed circuit board.

FIG. 2 is a process diagram illustrating an example of a method for manufacturing a printed circuit board.

FIG. 3 is a cross-sectional view illustrating an example of a semiconductor device.

### DESCRIPTION OF EMBODIMENTS

The present invention is not limited to the following examples. In the following description, the same or corresponding parts are denoted by the same reference numerals, and redundant description may be omitted. The positional relationship such as up, down, left, and right is based on the positional relationship illustrated in the drawings unless otherwise specified. The dimensional ratios in the drawings are not limited to the illustrated ratios. Terms such as “left”, “right”, “front”, “back”, “above”, “below”, “above”, “below” do not necessarily mean that their relative positions do not change. The term “layer” includes not only a structure having a shape formed on the entire surface but also a structure having a shape formed on a part thereof when observed as a plan view.

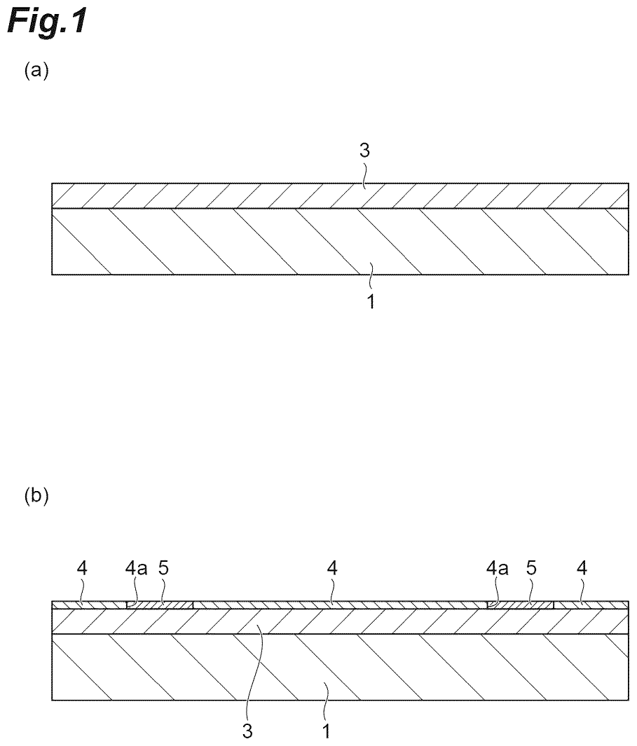

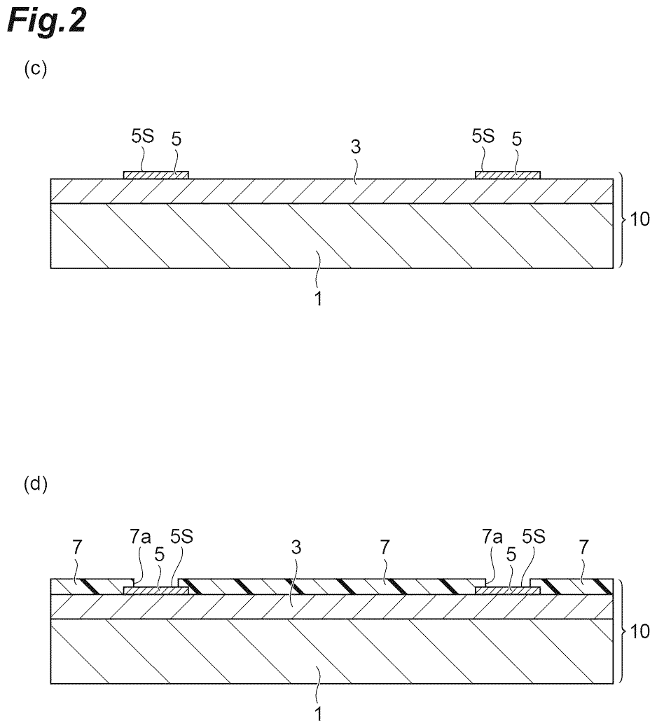

FIGS. 1 and 2 are process diagrams illustrating an example of a method for manufacturing a printed circuit board. The method illustrated in FIGS. 1 and 2 can include: preparing a printed circuit board 10 (wiring structure) including a base material 1, a wiring portion 3 provided on the base material 1, and an electrode pad 5 provided on a surface of the wiring portion 3 on a side opposite to the base material 1; and processing a connection surface 5S that is a surface of the electrode pad 5 on a side opposite to the wiring portion 3 so that the connection surface 5S is to be a surface having an arithmetic mean roughness Ra of 0.5 μm or more and 2.0 μm or less. In the present specification, a printed circuit board before a connection surface is processed may be referred to as a wiring structure.

The preparing of the printed circuit board 10 includes forming the wiring portion 3 including an insulating resin layer and a wiring layer on the main surface of the base material 1, and forming the electrode pad 5 on the surface of the wiring portion 3 on a side opposite to the base material 1.

The base material 1 may be, for example, a silicon substrate, a glass substrate, a stainless steel substrate, or glass cloth, or may be a semiconductor package having a semiconductor chip and a sealing resin layer for sealing the semiconductor chip.

The thickness of the base material 1 may be, for example, 0.2 mm or more and 2.0 mm or less. A base material having a thickness of 0.2 mm or more easily has good handleability. A base material having a thickness of 2.0 mm or less is often advantageous in terms of manufacturing cost. The base material 1 may be a wafer having a circular main surface or a panel having a rectangular main surface. For example, the base material 1 may be a wafer having a circular main surface having a diameter of 200 mm or more and 450 mm or less, or may be a panel having a rectangular main surface having a width of 300 mm or more and 700 mm or less.

The wiring portion 3 can be formed by a method including forming an insulating resin layer and a wiring layer provided in the insulating resin layer by an ordinary method. The wiring portion 3 may have a multilayer wiring structure including two or more wiring layers.

The electrode pad 5 can include, for example, forming a seed layer on a surface of the wiring portion 3 on a side opposite to the base material 1, forming a resist layer 4 having an opening 4a through which a part of the seed layer is exposed on the seed layer, forming an electrode pad 5 including an electrolytic plating layer filling the opening 4a, removing the resist layer 4, and removing a portion of the seed layer that is not covered with the electrolytic plating layer. The method for forming the seed layer may include washing the surface of the wiring portion 3 with a pretreatment liquid and adsorbing a palladium catalyst on the surface of the wiring portion 3. The seed layer may be formed by sputtering. The seed layer can be a metal layer containing a metal species such as copper or titanium. The thickness of the seed layer may be 20 nm or more and 200 nm or less, 40 nm or more and 200 nm or less, or 60 nm or more and 200 nm or less.

The electrode pad 5 may be a copper pad containing copper. The thickness of the electrode pad 5 may be 1 μm or more and 20 μm or less, 3 μm or more and 15 μm or less, or 5 μm or more and 15 μm or less.

The shape of the connection surface 5S of the electrode pad 5 or the opening 4a for forming the connection surface 5S may be circular or elliptical. The maximum widths of the electrode pad 5 (connection surface 5S) and the opening 4a may be 5 μm or more, or 20 μm or more, and may be 400 μm or less, or 300 μm or less, or 10 μm or less. The electrode pad 5 (connection surface 5S) and the opening 4a may have an area corresponding to the area of a circle having a diameter of 5 μm or more and 400 μm or less, or 5 μm or more and 10 μm or less.

The connection surface 5S of the prepared printed circuit board 10 is processed so as to be a surface having an arithmetic mean roughness Ra of 0.5 μm or more and 2.0 μm or less. It is advantageous that the arithmetic mean roughness Ra is large from the viewpoint of improving adhesion by the anchor effect, but according to findings by the present inventors, when the arithmetic mean roughness Ra exceeds 2.0 μm, defects such as cracks in an insulating resin layer (particularly, a surface insulating resin layer 7 to be described later) in contact with the connection surface 5S are likely to occur. The arithmetic mean roughness Ra can be measured by a method in accordance with JIS B0601-1994.

In a case where the connection surface 5S before being processed has the arithmetic mean roughness Ra of less than 0.5 μm, the connection surface 5S is roughened so that the arithmetic mean roughness Ra is 0.5 μm or more and 2.0 μm or less. In a case where the connection surface 5S before being processed has the arithmetic mean roughness Ra exceeding 2.0 μm, the connection surface 5S is smoothed so that the arithmetic mean roughness Ra is 0.5 μm or more and 2.0 μm or less. The roughening treatment and the smoothing treatment may include bringing the connection surface 5S into contact with the treatment liquid. The treatment liquid for the roughening treatment may be, for example, an acidic aqueous solution. The acidic aqueous solution may include an organic or inorganic acid, a cupric ion source, a halide ion source, and a polymer. The organic acid may be, for example, formic acid, acetic acid, propionic acid, butyric acid, or a combination thereof. The inorganic acid may be, for example, sulfuric acid, hydrochloric acid, or a combination thereof. The halide may be, for example, hydrochloric acid, hydrobromic acid, sodium chloride, potassium chloride, calcium chloride, potassium bromide, or a combination thereof. The cupric ion source may be, for example, cupric chloride, cupric bromide, cupric hydroxide, cupric oxide or a combination thereof. The polymer may have a polyamine chain or a cationic group (e.g., a quaternary ammonium group). The treatment liquid for the smoothing treatment can be selected from, for example, a treatment liquid containing an imidazole compound and a sugar alcohol, a treatment liquid containing an aromatic compound having an amino group and an aromatic ring, a polybasic acid and a halide ion or an oxidizing agent (hypochlorous acid, chlorous acid, chloric acid, perchloric acid, persulfuric acid, percarbonic acid, hydrogen peroxide, organic peroxide, and the like), a treatment liquid containing an aromatic compound having an amino group and an aromatic ring and a thio compound, and a treatment liquid containing a silane coupling agent, a metal ion and a halide ion.

In the connection surface 5S after the treatment, the number of protrusions having a height exceeding 3 μm may be 5 or less per 15 μm length in the in-plane direction of the connection surface 5S. A relatively large protrusion having a height exceeding 3 μm may be a starting point of a defect such as a crack in the surface insulating resin layer. The height of the protrusion is a height based on the deeper one of the bottoms of the recesses on both sides of the protrusion when the unevenness of the connection surface 5S is measured along the in-plane direction of the connection surface 5S. The number of protrusions having a height exceeding 3 μm may be 4 or less, 3 or less, 2 or less, or 1 or less per 15 μm length of the connection surface 5S in the in-plane direction.

After the processing of the connection surface 5S, a surface insulating resin layer 7 provided on the surface of the wiring portion 3 on a side opposite to the base material 1 and having an opening 7a through which the central portion of the electrode pad 5 is exposed is formed. The surface insulating resin layer 7 is formed so as to be in contact with the peripheral edge portion of the connection surface 5S. The thickness of the portion of the surface insulating resin layer 7 in contact with the wiring portion 3 may be 15 μm or more and 30 μm or less.

The surface insulating resin layer 7 can be formed of, for example, a resist material usually used for forming a solder resist. The opening 7a can be formed by, for example, laser ablation, photolithography (exposure and development), or imprinting. The material for forming the surface insulating resin layer 7 may be a thermosetting or photocurable resist material. In the case of photolithography, a photocurable resist material is used.

The thermosetting resist material may contain a thermosetting resin that is cured by heating to form a cured product exhibiting electrical insulation. The thermosetting resin may be, for example, an epoxy resin, a phenol resin, a triazine ring-containing resin, an unsaturated polyester resin, a bismaleimide resin, a diallyl phthalate resin, a silicone resin, a resin having a benzoxazine ring, a norbornene-based resin, a cyanate resin, an isocyanate resin, a urethane resin, a benzocyclobutene resin, a maleimide resin, a bismaleimide triazine resin, a polyazomethine resin, a thermosetting polyimide, or a combination thereof. Examples of the epoxy resin include bisphenol type epoxy resins such as bisphenol A type epoxy resin, bisphenol F type epoxy resin, bisphenol S type epoxy resin, bisphenol E type epoxy resin, bisphenol M type epoxy resin, bisphenol P type epoxy resin, and bisphenol Z type epoxy resin; novolac type epoxy resins such as bisphenol A novolac type epoxy resin, phenol novolac type epoxy resin, and cresol novolac epoxy resin; biphenyl type epoxy resins; biphenyl aralkyl type epoxy resins; aryl alkylene type epoxy resins; tetraphenylolethane type epoxy resins; naphthalene type epoxy resins; anthracene type epoxy resins; phenoxy type epoxy resins; dicyclopentadiene type epoxy resins; norbornene type epoxy resins; adamantane type epoxy resins; fluorene type epoxy resins; glycidyl methacrylate copolymer epoxy resins; a copolymer of cyclohexyl maleimide and glycidyl methacrylate, an epoxy-modified polybutadiene rubber derivative, a CTBN-modified epoxy resin, trimethylolpropane polyglycidyl ether, phenyl-1,3-diglycidyl ether, biphenyl-4,4′-diglycidyl ether, 1,6-hexanediol diglycidyl ether, diglycidyl ether of ethylene glycol or propylene glycol, sorbitol polyglycidyl ether, tris(2,3-epoxypropyl) isocyanurate, and triglycidyl tris(2-hydroxyethyl) isocyanurate. Examples of the phenolic resin include novolak type phenolic resins such as phenol novolak resins, cresol novolak resins and bisphenol A novolak resins, unmodified resol phenolic resins, and resol type phenolic resins such as oil-modified resol phenolic resins modified with tung oil, linseed oil, walnut oil or the like. Examples of the triazine ring-containing resin include urea resins and melamine resins.

The photocurable resist material may include, for example, a photocurable resin that is an epoxy resin (alicyclic epoxy resin or the like), an oxetane compound, a vinyl ether compound, or a combination thereof. Examples of cycloaliphatic epoxy resins include 3,4,3′,4′-diepoxy bicyclohexyl, 2,2-bis(3,4-epoxycyclohexyl) propane, 2,2-bis(3,4-epoxycyclohexyl)-1,3-hexafluoropropane, bis(3,4-epoxycyclohexyl) methane, 1-[1,1-bis(3,4-epoxycyclohexyl)] ethylbenzene, bis(3,4-epoxycyclohexyl) adipate, 3,4-epoxycyclohexylmethyl (3,4-epoxy) cyclohexanecarboxylate, (3,4-epoxy-6-methylcyclohexyl)methyl-3′,4′-epoxy-6-methylcyclohexanecarboxylate, ethylene-1,2-bis(3,4-epoxycyclohexanecarboxylic acid) ester, cyclohexene oxide, 3,4-epoxycyclohexylmethyl alcohol, and 3,4-epoxycyclohexylethyltrimethoxysilane.

The material for forming the surface insulating resin layer 7 may contain a thermoplastic resin. The thermoplastic resin can be a general-purpose plastic, an engineering plastic, a thermoplastic elastomer, or a combination thereof. Examples of general-purpose plastics include acrylic resins, modified acrylic resins, low-density polyethylene, high-density polyethylene, ethylene-vinyl acetate copolymers, polyethylene terephthalate, polypropylene, modified polypropylene, polystyrene, acrylonitrile-butadiene-styrene copolymers, acrylonitrile-styrene copolymers, cellulose acetate, polyvinyl alcohol, polyvinyl chloride, polyvinylidene chloride, and polylactic acid. Examples of engineering include polyamide, thermoplastic polyurethane, polyacetal, polycarbonate, ultra-high molecular weight polyethylene, polybutylene terephthalate, modified polyphenylene ether, polysulfone, polyphenylene sulfide, polyether sulfone, polyether ether ketone, polyarylate, polyether imide, polyamide imide, liquid crystal polymer, polyamide 6T, polyamide 9T, polytetrafluoroethylene, polyvinylidene fluoride, polyester imide, and thermoplastic polyimide. Examples of the thermoplastic elastomer include an olefin-based thermoplastic elastomer, a styrene-based thermoplastic elastomer, a polyester-based thermoplastic elastomer, a urethane-based thermoplastic elastomer, an amide-based thermoplastic elastomer, a vinyl chloride-based thermoplastic elastomer, and a hydrogenated thermoplastic elastomer.

The material for forming the surface insulating resin layer 7 may contain an inorganic filler. The inorganic filler can contribute to improvement of reliability and rigidity of the surface insulating resin layer 7. The inorganic filler can be, for example, silica, barium sulfate, barium titanate, talc, clay, calcined kaolin, magnesium carbonate, calcium carbonate, aluminum oxide, aluminum hydroxide, mica powder, or a combination thereof.

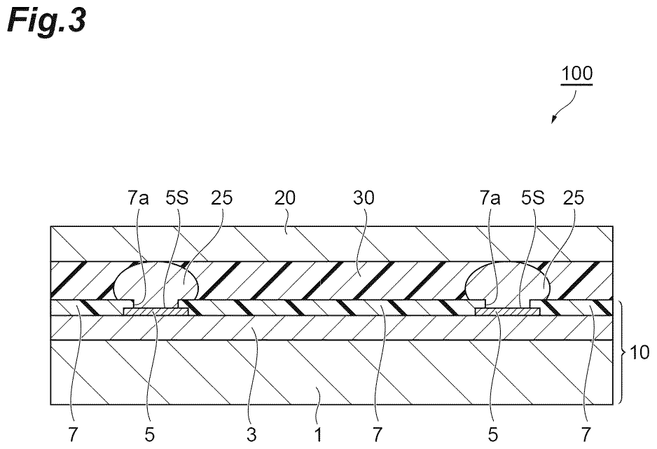

A semiconductor device can be obtained by mounting a semiconductor chip on the printed circuit board obtained by the above method. FIG. 3 is a cross-sectional view illustrating an example of the semiconductor device. A semiconductor device 100 illustrated in FIG. 3 includes a printed circuit board 10, a semiconductor chip 20 mounted on the printed circuit board 10, a solder bump 25 interposed between the semiconductor chip 20 and an electrode pad 5 of the printed circuit board 10 and electrically connecting them, and an insulating resin layer 30 (adhesive layer) filled between the semiconductor chip 20 and the printed circuit board 10.

Even in a semiconductor device having fine wiring and a large number of pins, occurrence of cracks in the insulating resin layer can be effectively suppressed. The semiconductor device may have an interposer including a fine wiring layer for mixedly mounting different types of semiconductor chips. For example, the interval between the pins provided on the semiconductor chip may be 200 μm or less, 100 μm or less, or 30 μm or more. The number of pins provided on the semiconductor chip may be 500 or more, 1000 or more, or 10,000 or less.

### Examples

The present invention is not limited to the following examples.

A printed circuit board having a copper pad having a connection surface (width: 260 μm) having an arithmetic mean roughness Ra of 0.03 μm and a surface insulating resin layer (solder resist) having an opening through which the copper pad has been exposed has been prepared. The connection surface of the copper pad has been roughened with a roughening solution to form a surface having an arithmetic mean roughness Ra of 0.5 μm, 1.0 μm, 2.0 μm, 3.0 μm, or 5.0 μm. The arithmetic mean roughness Ra has been measured using a laser microscope (OLS4100 manufactured by Olympus Corporation). The semiconductor chip has been mounted on the printed circuit board using a nitrogen reflow furnace so as to be connected to the connection surface after the treatment via solder bumps. The temperature of the nitrogen reflow furnace has been set to 260° C. It has been confirmed that the solder bump and the semiconductor chip have been connected to the printed circuit board, and an insulating resin layer has been filled between the semiconductor chip and the printed circuit board and thermally cured. The formed semiconductor device has been put into a temperature cycle tester, and subjected to 400 cycle heat treatment under conditions of a high temperature side of 165° C., a low temperature side of −65° C., and a retention time of 15 minutes.

The cross section of the surface insulating resin layer in the vicinity of the copper pad in the heat-treated semiconductor device has been observed to confirm the presence or absence of cracks. The results are shown in Table 1. It has been confirmed that the occurrence of cracks in the surface insulating resin layer has been effectively suppressed by forming the connection surface having Ra of 0.5 μm or more and 2.0 μm or less. In a case where Ra has been 0.03 μm, interfacial peeling has been observed between the connection surface and the surface insulating resin layer, suggesting insufficient adhesion.

TABLE 1

| | Copper pad connection surface Ra [μm] | | | | | |
|---|---|---|---|---|---|---|
| | 0.03 | 0.5 | 1.0 | 2.0 | 3.0 | 5.0 |
| Cracks | Present | Absent | Absent | Absent | Present | Present |

### REFERENCE SIGNS LIST

3 Wiring portion
4a, 7a Opening
5 Electrode pad
5S Connection surface
7 Surface insulating resin layer
10 Printed circuit board (wiring structure)
20 Semiconductor chip
25 Solder bump
100 Semiconductor device

1. A printed circuit board comprising:
a wiring portion comprising a wiring layer; and
an electrode pad provided on the wiring portion and connected to the wiring layer, wherein
a connection surface that is a surface of the electrode pad on a side opposite to the wiring portion has an arithmetic mean roughness Ra of 0.5 μm or more and 2.0 μm or less.

2. The printed circuit board according to claim 1, wherein a number of protrusions having a height exceeding 3 μm on the connection surface is 5 or less per 15 μm length in an in-plane direction of the connection surface.

3. The printed circuit board according to claim 1, further comprising
a surface insulating resin layer provided on a surface of the wiring portion on the electrode pad side and having an opening configured to expose the electrode pad, wherein
the surface insulating resin layer is in contact with a part of the connection surface.

4. The printed circuit board according to claim 3, wherein the surface insulating resin layer is a layer formed of a thermosetting or photocurable resist material comprising an epoxy resin.

5. A semiconductor device comprising:
the printed circuit board according to claim 1; and
a semiconductor chip mounted on the printed circuit board.

6. A method for manufacturing a printed circuit board, the method comprising:
preparing a wiring structure comprising a wiring portion comprising a wiring layer and an electrode pad provided on the wiring portion; and
processing a connection surface that is a surface of the electrode pad on a side opposite to the wiring portion so that the connection surface has a surface having an arithmetic mean roughness Ra of 0.5 μm or more and 2.0 μm or less.

7. The method according to claim 6, wherein the connection surface is processed to have a surface having an arithmetic mean roughness Ra of 0.5 μm or more and 2.0 μm or less, and to have a number of protrusions with a height exceeding 3 μm of 5 or fewer per 15 μm length in an in-plane direction of the connection surface.

8. The method according to claim 6, further comprising:
forming a surface insulating resin layer having an opening configured to expose the connection surface on a surface of the wiring portion on the electrode pad side, wherein
the surface insulating resin layer is formed so as to be in contact with a part of the connection surface.

9. The method according to claim 8, wherein the surface insulating resin layer is formed of a thermosetting or photocurable resist material comprising an epoxy resin.
